(19) United States
(12) Patent Application Publication
(10) Pub. No.: US 2022/0074675 A1
(43) Pub. Date: Mar. 10, 2022

(54) HEAT TRANSPORT SYSTEM

(71) Applicant: TKR CORPORATION, Tokyo (JP)

(72) Inventor: Eiji OSHIMA, Tokyo (JP)

(21) Appl. No.: 17/350,876

(22) Filed: Jun. 17, 2021

(30) Foreign Application Priority Data
Jun. 17, 2020 (JP) 2020-104771

(51) Int. Cl. F28D 15/04; H01L 23/427

(52) U.S. Cl. CPC F28D 15/04; H01L 23/427

(57) ABSTRACT

Provided is a heat transport device that has high heat transport capability despite being small and lightweight. The heat transport device includes a flat plate-shaped base having a heat receiving surface that contacts a heating element, multiple flow paths that extend in the base so as to be approximately in parallel with the heat receiving surface, and working fluid sealed in the flow paths. The base is formed of a photocurable synthetic resin. The flow paths have multiple concave grooves formed on the inner circumferential walls of circular main flow paths. The grooves are disposed so as to be inclined with respect to the axial direction of the flow paths.

### TECHNICAL FIELD

The present invention relates to a heat transport device that when contacted with a heating element such as a semiconductor device or electronic component, transports heat released from the heating element using the phase transition of working fluid.

### BACKGROUND ART

Many semiconductor devices having high current density, such as a semiconductor integrated circuit, an LED device, and a power semiconductor, are mounted on electronic devices, industrial machines, automobiles, and the like for the purpose of enhancing the performance of the electronic devices and the like or combining the functions thereof. When the amount of current flowing into a semiconductor device in an electronic device or the like is increased, the semiconductor device generates heat. Such heat generation of the semiconductor device often leads to a reduction in the performance or reliability of the electronic device or the like. To suppress an increase in the temperature due to heat generation of a semiconductor device, a configuration that contacts a heat sink formed of a metal material having a high thermal conductivity with a semiconductor device, transports heat generated by the semiconductor device to the low temperature-side, for example, a fin, by thermal conduction in the heat sink, and releases the heat from the fin into the air is typical.

It has been revealed in recent years that mobile electronic devices, such as smartphones, portable information terminals, tablet terminals, and notebook personal computers, also face such a heat problem associated with size reduction and performance enhancement. A semiconductor device, such as SoC, mounted on a mobile electronic device becomes a very high temperature despite being small in size. For this reason, it is necessary to suppress occurrence of a local high-temperature area due to such heat generation of the semiconductor device. There is a structural limit to size reduction of a heat sink as described above, and it is difficult to mount the heat sink on a mobile electronic device. A vapor chamber is a device that efficiently transports heat using the phase transition of working fluid, such as water, and is characterized in that it can be relatively thinned. A vapor chamber mounted on a mobile electronic device is able to efficiently diffuse heat from a semiconductor device, such as SoC.

A heat transport device (vapor chamber) described in Japanese Unexamined Patent Application Publication No. 2011-102691 includes a casing formed of aluminum, a waterproof layer formed inside the casing, and a capillary structure layer formed on the waterproof layer. Since the waterproof layer and the powdery, porous capillary structure layer are formed on the inner wall of the casing by thermal spraying, this heat transport device is able to use water as working fluid.

See Japanese Unexamined Patent Application Publication No. 2011-102691.

### SUMMARY OF INVENTION

Although the heat transport device of Japanese Unexamined Patent Application Publication No. 2011-102691 is able to use water, which has high heat transport capability, this heat transport device is difficult to reduce in size or weight since it is produced by machining. For this reason, there is a limit to size or weight reduction of heat transport devices corresponding to further performance enhancement and size reduction of mobile electronic devices.

The present invention has been made in view of the above problem, and an object thereof is to provide a heat transport device that has high heat transport capability despite being small and lightweight.

To solve the above problem, a heat transport device according to the present invention includes a base having a heat receiving surface that contacts a heating element, multiple flow paths that extend in the base so as to be approximately in parallel with the heat receiving surface, and working fluid sealed in the flow paths. The base is formed of a photocurable synthetic resin. The flow paths have multiple concave grooves formed on inner circumferential walls of circular tubular main flow paths. The grooves are disposed so as to be inclined with respect to an axial direction of the flow paths.

A heat transport device according to the present invention includes a base having a heat receiving surface that contacts a heating element, a heat receiving space formed in the base, multiple heat pipes extending from a surface opposite to the heat receiving surface of the base, flow paths disposed in the heat pipes and communicating with the heat receiving space, and working fluid sealed in the heat receiving space. The base and the heat pipes are formed of a photocurable synthetic resin. The flow paths have multiple concave grooves formed on inner circumferential walls of circular tubular main flow paths. The grooves are disposed so as to be inclined with respect to an axial direction of the flow paths.

When the heating element contacts the heat receiving surface of the heat transport device according to the present invention, the heat of the heating element is transmitted to the flow paths in the base through the heat receiving surface. As the heat of the heating element is transmitted to the working fluid sealed in the flow paths, the saturated vapor pressure of the working fluid is increased and thus the working fluid is transferred from the liquid phase to the gaseous phase. The heat transmitted from the heat receiving surface is absorbed as the latent heat of vaporization of the working fluid and thus an increase in the temperature of the heat receiving surface is suppressed. On the other hand, the working fluid transferred to the gaseous phase is diffused in the flow paths and condensed in areas having a relatively low temperature. At this time, the working fluid releases the latent heat. The condensed working fluid is refluxed to near the heat receiving surface through the grooves by the capillary force. Due to the circulation of the working fluid using such a phase change, the heat is favorably transported. The working fluid is preferably condensable fluid that vaporizes and condenses in the desired temperature range. Examples include pure water, alcohols such as ethanol, fluorine-based inert liquid, ammonia, and CFC substitute such as HFC-134a.

Conventionally, a heat transport device that circulates working fluid using a phase change, for example, a vapor chamber, is formed by working a metal, such as aluminum. There is a limit to cost reduction or size reduction of a heat transport device in terms of the characteristics of metalworking. The heat transport device according to the present invention is formed of the photocurable synthetic resin. For this reason, it can be easily reduced in size or weight using additive manufacturing technology. For example, vat photopolymerization (stereolithography), which forms a three-dimensional object by selectively solidifying a photocurable resin using light, can be used to form a fine, high-resolution three-dimensional object. Examples of available photocurable synthetic resins include acrylate-based monomers having a heat resistance of 250° C.

The reflux of the working fluid depends on the capillary force of the grooves and the ease of flow of the working fluid. The capillary force produces a driving force required to circulate the working fluid by feeding it from the condensing portion to the evaporating portion. The ease of flow of the working fluid means the heat resistance of the grooves. An improvement in the ease of flow of the working fluid leads to a reduction in the heat resistance of the grooves. To increase the heat transport capability of the heat transport device, it is necessary to improve both the capillary force and the ease of flow of the working fluid. However, these two elements have a trade-off relationship. This is because when the radius of the grooves is reduced by reducing the size of the heat transport device, the capillary force is increased but the ease of flow of the working fluid is reduced. It is difficult to improve both the capillary force and the ease of flow of the working fluid.

When grooves are formed by machining as in a conventional heat transport device, grooves that are linear along the axial direction of the flow paths are formed. The grooves that are linear in the axial direction causes a head-on collision between the vaporized working fluid and the liquidized working fluid and thus reduces the ease of flow of the working fluid in the grooves. In the present invention, the heat transport device is formed of the synthetic resin, and the grooves are disposed so as to be inclined with respect to the axial direction of the flow paths. The inclined grooves avoid a head-on collision between the vaporized working fluid and liquidized working fluid and improves the ease of flow of the working fluid in the grooves. As seen above, the heat transport device according to the present invention has high heat transport capability despite being small and lightweight.

Mobile electronic devices, such as smartphones and tablet terminals, are strongly required to enhance performance, as well as to be thinned. The amount of heat generated by mobile devices has been continuously increased as performance is enhanced. In particular, local heat generated by semiconductor devices, such as SoC, including a CPU has become a problem. In the heat transport device according to the present invention, the multiple flow paths extend in the flat plate-shaped base so as to be approximately in parallel with respect to the heat receiving surface. Such disposition of the flow paths suppresses the height from the heat receiving surface and thus allows for realization of a very thin heat transport device suitable to be mounted on a mobile electronic device, such as a smartphone.

Many semiconductor devices having high current density, such as a semiconductor integrated circuit, an LED device, and a power semiconductor, are mounted on electronic devices, industrial machines, automobiles, and the like. For a heat transport device used to cool such a semiconductor device, the capability to efficiently dissipate heat from the heating element is important. In the heat transport device according to the present invention, the multiple heat pipes are disposed so as to extend from the surface opposite to the heat receiving surface of the base, and the flow paths are formed in the heat pipes. the heat flowing in through the heat receiving surface vaporizes the working fluid in the heat receiving space of the base. The working fluid transferred to the gaseous phase is diffused in the flow paths of the heat pipes and condensed in areas having a relatively low temperature, that is, at the tips of the heat pipes. At this time, the working fluid releases the latent heat. Such a configuration, that is, the extension of the multiple heat pipes from the base increases the dissipation efficiency of the heat transport device.

In the heat transport device having the above configuration, the following condition expression is preferably satisfied:

D≤30° (1)

where D represents an inclination angle of the grooves with respect to the axial direction of the flow paths.

As described above, inclining the grooves in the flow paths with respect to the axial direction of the flow paths improves the ease of flow of the working fluid in the grooves. However, if the grooves are inclined excessively, the influence of gravity, or the like would make it difficult for the working fluid in the grooves to flow. When the condition expression (1) is satisfied, the working fluid is efficiently refluxed through the grooves, resulting in an improvement in the heat transport capability of the heat transport device.

In the heat transport device having the above configuration, the main flow paths of the flow paths preferably each have a diameter of 1.5 mm or less.

In the heat transport device having the above configuration, the grooves preferably each have a radius of 0.25 mm or less. Reducing the radius of the grooves increases the capillary force and thus facilitates reflux of the condensed working fluid.

In the heat transport device having the above configuration, a film having a higher thermal conductivity than the synthetic resin is preferably formed as an inner surface.

Examples of a method for forming the film having a higher thermal conductivity than the synthetic resin include electroless plating with nickel, copper, or the like and application of a coat having a high thermal conductivity. Electroless plating is a film formation method of forming a uniform plating film by immersing a material in a plating solution. Electroless plating allows for formation of a plating film not only on a metal material but also on a synthetic resin material. By forming such a film having a high thermal conductivity inside the heat transport device, the heat transport device is able to perform heat dissipation with an improved efficiency when a large amount of heat is generated by the heating element. Note that the thickness of the plating film can be controlled using the conditions, such as the temperature of the plating solution and the immersion time. For this reason, the thickness of plating is preferably determined in accordance with the heat transport efficiency or heat dissipation efficiency the heat transport device is required to have.

In the heat transport device having the above configuration, a film having a higher thermal conductivity than the synthetic resin is preferably formed as an outer surface. This is useful in terms of an improvement in the heat dissipation efficiency of the heat transport device.

The plating film need not be formed using electroless plating. Any plating method may be used as long as a plating film having a high thermal conductivity is formed. Coating using heat radiation has debuted in recent years. Such coating also can improve the heat dissipation efficiency of the heat transport device.

The heat transport device according to the present invention has high heat transport capability despite being small and lightweight.

### BRIEF DESCRIPTION OF DRAWINGS

FIG. 1 is a perspective view schematically showing the appearance of a heat transport device according to a first embodiment of the present invention;

FIG. 2 is a front view of the heat transport device shown in FIG. 1;

FIG. 3 is an exploded perspective view of the heat transport device shown in FIG. 1;

FIG. 4 is a sectional view taken along line A-A of the heat transport device shown in FIG. 2;

FIG. 5 is a sectional view taken along line B-B of the heat transport device shown in FIG. 2;

FIG. 6 is a perspective view schematically showing the appearance of a heat transport device according to a second embodiment of the present invention;

FIG. 7 is a plan view of the heat transport device shown in FIG. 6;

FIG. 8 is a front view of the heat transport device shown in FIG. 6;

FIG. 9 is a sectional view taken along line A-A of the heat transport device shown in FIG. 7;

FIG. 10 is a sectional view taken along line B-B of the heat transport device shown in FIG. 7;

FIG. 11 is a perspective view taken along line C-C of the heat transport device shown in FIG. 8;

FIG. 12 is a sectional view taken along line C-C of the heat transport device shown in FIG. 8; and

FIG. 13 is an enlarged view schematically showing the flow paths of the heat transport device shown in FIG. 11.

### DESCRIPTION OF EMBODIMENTS

### First Embodiment

Now, a first embodiment of the present invention will be described in detail with reference to the accompanying drawings.

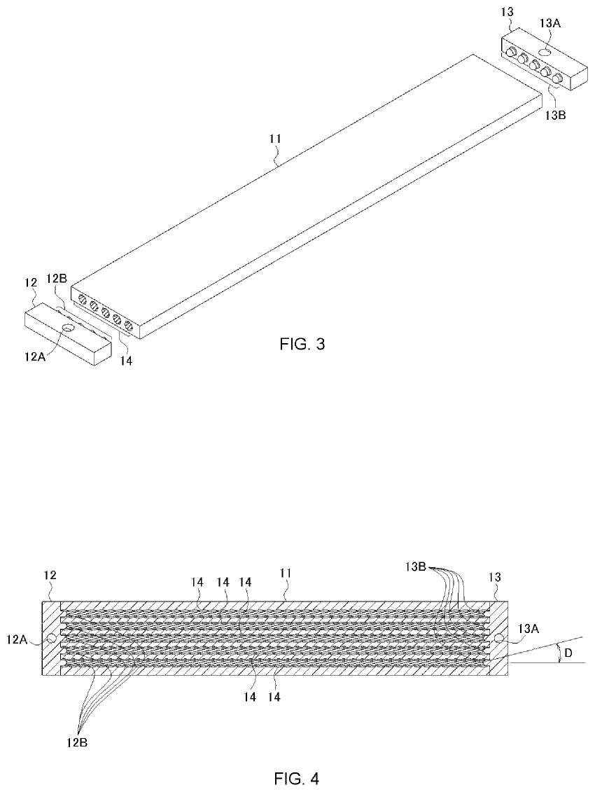

A heat transport device according to the present embodiment is assumed to be incorporated into a mobile electronic device, such as a smartphone, portable information terminal, tablet terminal, or notebook personal computer. As shown in FIGS. 1 to 3, a heat transport device 10 includes a rectangular parallelepiped base 11 in the shape of a flat plate and first and second sealing members 12 and 13 disposed such that both sides in the side direction of the base 11 are sandwiched therebetween. The base 11 and the first and second sealing members 12 and 13 are formed of a photocurable synthetic resin. Among methods for forming a three-dimensional object is vat photopolymerization (stereolithography), which forms a three-dimensional object by selectively solidifying a photocurable synthetic resin. In the present embodiment, the base 11 and the first and second sealing members 12 and 13 are formed by stereolithography using acrylate-based monomers having a heat resistance of 250° C. as a material. Note that the bottom surface of the base 11 serves as a heat receiving surface 11A.

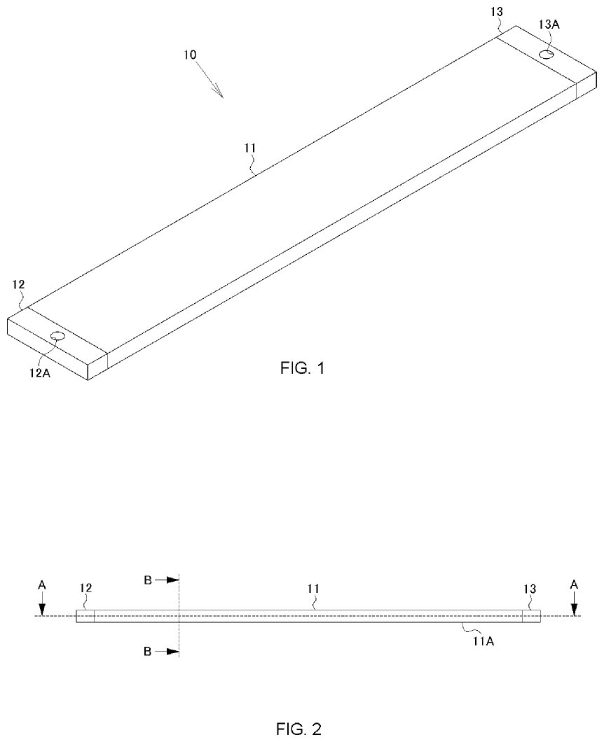

Multiple flow paths 14 extend approximately in parallel with the heat receiving surface 11A in the base 11. The flow paths 14 are formed so as to penetrate the base 11 from one side to the other side in the left-right direction in FIG. 2.

The first and second sealing members 12 and 13 are in the shape of a rectangular parallelepiped. Mounting holes 12A and 13A are formed so as to penetrate the first and second sealing members 12 and 13, respectively, in the up-down direction in FIG. 2. The mounting holes 12A and 13A are used to mount the heat transport device 10 on a circuit board having a semiconductor device or the like acting as a heating element mounted thereon. The first and second sealing members 12 and 13 include seal protrusions 12B and 13B, respectively, that correspond to the number of flow paths 14 and protrude in the left-right direction in FIG. 2. Specifically, the first sealing member 12 includes the seal protrusions 12B protruding rightward, and the second sealing member 13 includes the seal protrusions 13B protruding leftward. The seal protrusions 12B and 13B are in the shape of a cylinder whose tip is a spherical surface. The diameter of the cylindrical seal protrusions 12B and 13B is approximately the same as the diameter of the main flow paths of the flow paths 14.

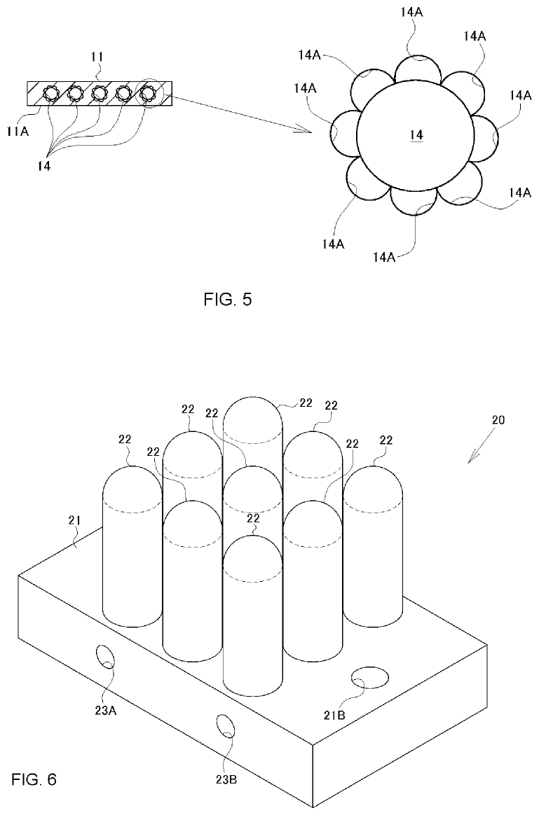

The flow paths 14 will be described in detail below. As shown in FIGS. 4 and 5, the flow paths 14 are disposed in parallel at equal intervals in the base 11. In the present embodiment, five flow paths 14 are disposed in the base 11. The number of flow paths 14 can be increased and reduced in accordance with the amount of heat generated by the heating element. The flow paths 14 has multiple concave grooves 14A formed on the inner circumferential walls of the circular tubular main flow paths. The grooves 14A are disposed so as to be inclined with respect to the axial direction of the flow paths 14. Specifically, the inclination angle D (lead angle) of the grooves 14A with respect to the axial direction of the flow paths 14 satisfies the following condition expression (1).

D≤30° (1)

In the present embodiment, the main flow paths of the flow paths 14 each have a diameter of 1.0 mm, and the grooves 14A consist of 8 grooves and each have a radius of 0.2 mm. Both the main flow paths and grooves 14A of the flow paths 14 are preferably thin in terms of reduction in size and improvement in the heat transport capability of the heat transport device 10. In the present embodiment, the dimensions of the main flow paths and grooves 14A of the heat transport device 10 are determined considering the ease of production. In the heat transport device 10, the base 11 is formed of the photocurable synthetic resin and therefore the diameter of the main flow paths and the radius of the grooves 14A can be further reduced.

The inner surfaces and outer surfaces of the base 11 and the first and second sealing members 12 and 13 are electroless-plated with nickel, copper, or the like. The thermal conductivity of the electroless plating is higher than the thermal conductivity of the synthetic resin, which is the material of these members, and therefore the heat dissipation capability of the heat transport device 10 is improved.

The assembly of the members described above will be described briefly. First, the first sealing member 12 is joined to the base 11 by fitting the seal protrusions 12B of the first sealing member 12 to the flow paths 14. Then, working fluid is injected into the flow paths 14 of the base 11. Examples of the working fluid include pure water, alcohols such as ethanol, fluorine-based inert liquid, ammonia, and CFC substitute such as HFC-134a. Then, the second sealing member 13 is joined to the base 11 by fitting the seal protrusions 13B of the second sealing member 13 to the flow paths 14. Thus, the working fluid is sealed in the flow paths 14 of the heat transport device 10.

Next, heat transport performed by the heat transport device 10 according to the present embodiment will be described. The heat transport device 10 is mounted on the circuit board such that the heat receiving surface 11A of the base 11 contacts the semiconductor device, such as SoC. When the semiconductor device generates heat, the heat is transmitted to the working fluid in the flow paths 14 through the heat receiving surface 11A. As a result, the saturated vapor pressure of the working fluid sealed in the flow paths 14 is increased, and the working fluid is transferred from the liquid phase to the gaseous phase. The working fluid absorbs the heat transmitted through the heat receiving surface 11A as the latent heat of vaporization and thus suppresses an increase in the temperature of the heat receiving surface 11A. On the other hand, the working fluid transferred to the gaseous phase is diffused in the flow paths 14 and condensed in areas having a relatively low temperature. At this time, the latent heat of the working fluid is released. The condensed working fluid is refluxed to near the heat receiving surface 11A through the grooves 14A by the capillary force. Due to the circulation of the working fluid using such a phase change, the heat is favorably transported.

Thus, the heat transport device 10 according to the present embodiment is able to efficiently diffuse the heat released from the semiconductor device incorporated into the mobile electronic device, such as the smartphone, portable information terminal, tablet terminal, or notebook personal computer, as well as to diffuse the heat in the ambient air. As a result, the heat transport device 10 according to the present embodiment is able to suppress an increase in the temperature caused by the heat generation of the semiconductor device and thus to suppress a reduction in the performance or reliability of the mobile electronic device.

### Second Embodiment

Next, a second embodiment of the present invention will be described in detail with reference to the accompanying drawings.

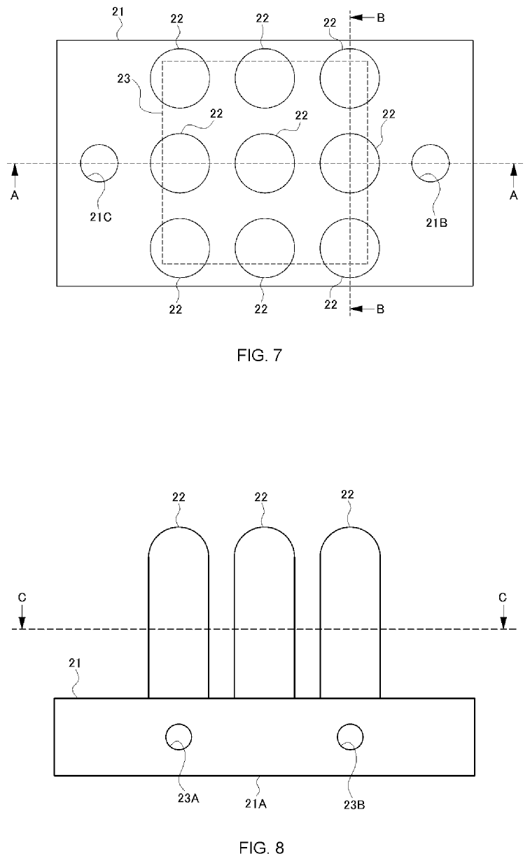

Electronic devices, industrial machines, automobiles, and the like include many semiconductor devices having high current density, such as a semiconductor integrated circuit, an LED device, and a power semiconductor. A heat transport device according to the present embodiment assumes the purpose of efficiently dissipating heat generated by such a semiconductor device. As shown in FIGS. 6 to 8, a heat transport device 20 includes a rectangular parallelepiped base 21 in the shape of a flat plate and multiple heat pipes 22 disposed so as to extend upward from the upper surface of the base 21. The base 21 and heat pipes 22 are integrally formed of a photocurable synthetic resin. As in the above-mentioned first embodiment, the heat transport device 20 is also formed by stereolithography using acrylate-based monomers having a heat resistance of 250° C. as a material. Note that the bottom surface of the base 21 serves as a heat receiving surface 21A.

A heat receiving space 23 is formed in the base 21. In the present embodiment, the heat receiving space 23 is a rectangular prism-shaped space formed below the heat pipes 22 and communicates with working fluid injection holes 23A and 23B disposed on the front surface of the base 21. Also, mounting holes 21B and 21C are formed in the base 21 so as to penetrate the base 21 in the up-down direction in FIG. 8. The mounting holes 21B and 21C are used to mount the heat transport device 20 on a circuit board or the like having a heating element mounted thereon.

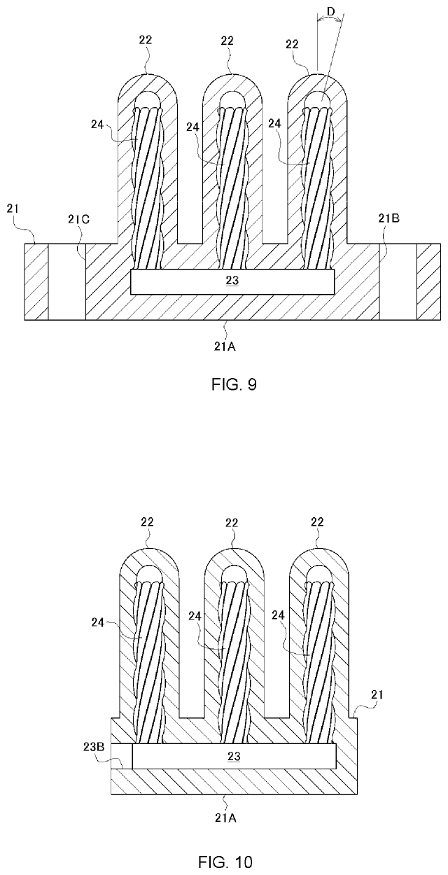

As shown in FIGS. 9 and 10, flow paths 24 communicating with the heat receiving space 23 are formed in the heat pipes 22. The flow paths 24 are formed from the upper surface of the heat receiving space 23 to the tips of the heat pipes 22 in the up-down direction in FIG. 9. All the flow paths 24 formed in the multiple heat pipes 22 communicate with the heat receiving space 23.

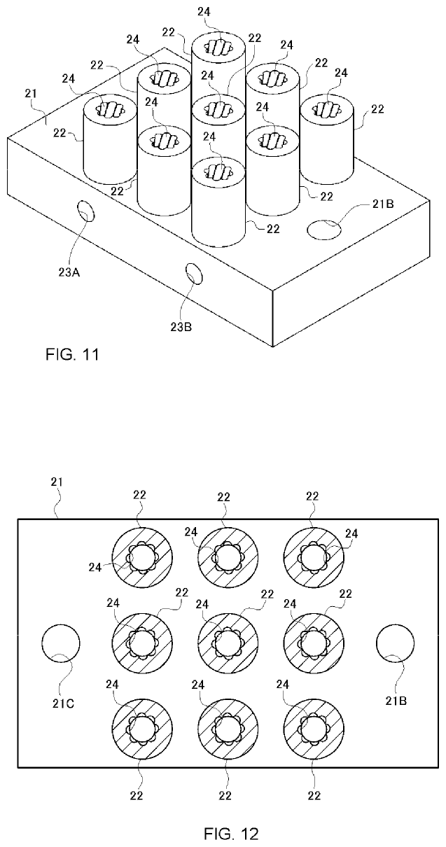

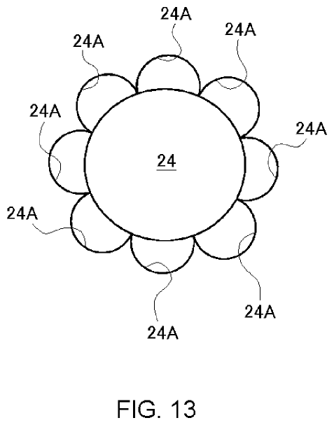

The flow paths 24 will be described in detail below. As shown in FIGS. 9 to 13, the flow paths 24 have multiple concave grooves 24A formed on the inner circumferential walls of the circular tubular main flow paths. The grooves 24A are disposed so as to be inclined with respect to the axial direction of the flow paths 24. As in the heat transport device 10 according to the first embodiment, the inclination angle D (lead angle) of the grooves 14A with respect to the axial direction of the flow paths 14 satisfies the following condition expression (1).

D≤30° (1)

In the present embodiment, the main flow paths of the flow paths 24 each have a diameter of 1.5 mm, and the grooves 24A consist of 8 grooves and each have a radius of 0.25 mm. Both the main flow paths and grooves 24A of the flow paths 24 are preferably thin in terms of reduction in size and improvement in the heat transport capability of the heat transport device 20. In the present embodiment, the dimensions of the main flow paths and grooves 24A of the heat transport device 20 are determined considering the ease of production. In the heat transport device 20, both the base 21 and heat pipes 22 are formed of the photocurable synthetic resin and therefore the diameter of the main flow paths and the radius of the grooves 24A can be further reduced.

The inner surfaces and outer surfaces of the base 21 and heat pipes 22 are electroless-plated with nickel, copper, or the like. The thermal conductivity of the electroless plating is higher than the thermal conductivity of the synthetic resin, which is the material of these members, and therefore the heat dissipation capability of the heat transport device 20 is improved.

In the heat transport device 20 described above, working fluid is injected into the heat receiving space 23 through the working fluid injection holes 23A and 23B of the base 21 and then is sealed in heat receiving space 23 by closing the working fluid injection holes 23A and 23B. Note that a separate condenser (radiator) may be connected to the working fluid injection holes 23A and 23B through tubes in place of closing the working fluid injection holes 23A and 23B.

Next, heat transport performed by the heat transport device 20 according to the present embodiment will be described. The heat transport device 20 is mounted on the circuit board such that the heat receiving surface 21A of the base 21 contacts the semiconductor device, such as a power semiconductor. When the semiconductor device generates heat, the heat is transmitted to the working fluid in the heat receiving space 23 through the heat receiving surface 21A. As a result, the saturated vapor pressure of the working fluid sealed in the heat receiving space 23 is increased, and the working fluid is transferred from the liquid phase to the gaseous phase. The working fluid absorbs the heat transmitted through the heat receiving surface 21A as the latent heat of vaporization and thus suppresses an increase in the temperature of the heat receiving surface 21A. On the other hand, the working fluid transferred to the gaseous phase is diffused in the flow paths 24 and condensed in areas having a relatively low temperature. In the heat transport device 20 according to the present embodiment, the working fluid condenses at the tips of the heat pipes 22 and releases the latent heat. The condensed working fluid is refluxed into the heat receiving space 23 through the grooves 24A by the capillary force. Due to the circulation of the working fluid using such a phase change, the heat is favorably transported.

Thus, the heat transport device 20 according to the present embodiment is able to efficiently diffuse the heat released from the semiconductor device, electronic component, or the like incorporated into the electronic device, industrial machine, automobile, or the like in the ambient air.

In the above embodiments, assuming that the heating element is a flat semiconductor device, the heat receiving surface 11A or 21A of the base 11 or 21 is formed so as to be flat. However, the shape of the heat receiving surface need not be flat. If the heating element has a curved surface, the heat receiving surface 11A or 21A may be formed as a curved surface. Since the bases 11 and 21 according to the above embodiments are formed of the photocurable synthetic resin, the heat receiving surface 11A or 21A can be formed into any shape by stereolithography. By forming the heat receiving surface of the base into a shape according to the shape of the heating element, as described above, the heating element and base are closely contacted and thus the heat of the heating element is efficiently transmitted to the base. If multiple heating elements are mounted on a circuit board or the like, the heat receiving surface of the base may be formed into a shape according to the shapes of the heating elements. By contacting the heat transport device closely with the multiple heating elements, the single heat transport device is able to efficiently transport and dissipate heat from the multiple heating elements.

The heat transport devices according to the above embodiments transport the heat from the heating element using the circulation of the working fluid based on the phase transition and thus are able to transport the heat more efficiently than heat transport using heat conduction in a solid performed by a typical heat sink or the like. While a heat transport device having such a configuration is conventionally formed by metalworking, the heat transport devices according to the above embodiments are formed of the photocurable synthetic resin. Thus, the heat transport devices can be reduced in size and weight. Also, the grooves of the flow paths are inclined. Thus, the reflux of the working fluid is promoted, and the heat transport efficiency is improved while suppressing dryout. The heat transport device according to the present invention has high heat transport capability despite being small and lightweight.

The present invention can be used for the purpose of suppressing a reduction in performance or reliability due to heat generation of a semiconductor device incorporated into a mobile electronic device such as a smartphone, or a semiconductor device incorporated into an industrial machine, automobile, or the like, or efficiently cooling such a semiconductor device.

1. A heat transport device comprising:
a base having a heat receiving surface that contacts a heating element;
a plurality of flow paths that extend in the base so as to be approximately in parallel with the heat receiving surface; and
working fluid sealed in the flow paths, wherein
the base is formed of a photocurable synthetic resin,
the flow paths have a plurality of concave grooves formed on inner circumferential walls of circular tubular main flow paths, and
the grooves are disposed so as to be inclined with respect to an axial direction of the flow paths.

2. A heat transport device comprising:
a base having a heat receiving surface that contacts a heating element;
a heat receiving space formed in the base;
a plurality of heat pipes extending from a surface opposite to the heat receiving surface of the base;
flow paths disposed in the heat pipes and communicating with the heat receiving space; and
working fluid sealed in the heat receiving space, wherein
the base and the heat pipes are formed of a photocurable synthetic resin,
the flow paths have a plurality of concave grooves formed on inner circumferential walls of circular tubular main flow paths, and
the grooves are disposed so as to be inclined with respect to an axial direction of the flow paths.

3. The heat transport device of claim 1, wherein D≤30° is satisfied where D represents an inclination angle of the grooves with respect to the axial direction of the flow paths.

4. The heat transport device of claim 1, wherein the main flow paths of the flow paths each have a diameter of 1.5 mm or less.

5. The heat transport device of claim 1, wherein the grooves each have a radius of 0.25 mm or less.

6. The heat transport device of claim 1, wherein a film having a higher thermal conductivity than the synthetic resin is formed as an inner surface.

7. The heat transport device of claim 1, wherein a film having a higher thermal conductivity than the synthetic resin is formed as an outer surface.

8. The heat transport device of claim 2, wherein D≤30° is satisfied where D represents an inclination angle of the grooves with respect to the axial direction of the flow paths.

9. The heat transport device of claim 2, wherein the main flow paths of the flow paths each have a diameter of 1.5 mm or less.

10. The heat transport device of claim 2, wherein the grooves each have a radius of 0.25 mm or less.

11. The heat transport device of claim 2, wherein a film having a higher thermal conductivity than the synthetic resin is formed as an inner surface.

12. The heat transport device of claim 2, wherein a film having a higher thermal conductivity than the synthetic resin is formed as an outer surface.
